(19) United States
(12) Patent Application Publication
(10) Pub. No.: US 2026/0305241 A1
(43) Pub. Date: Oct. 1, 2026

(54) YOKES, YOKE ASSEMBLIES AND SEMICONDUCTOR PROCESSING SYSTEMS INCLUDING YOKES, AND RELATED METHODS OF MAKING YOKES AND FORMING SEMICONDUCTOR STRUCTURES USING YOKES

(71) Applicant: ASM IP Holding B.V., Almere (NL)

(72) Inventors: Senthil Arasu Subas Chandra Bose, Chandler, AZ (US); Kyle Tantiwong, Scottsdale, AZ (US); Kenji Mizusawa, Tokyo (JP); Samer Banna, Phoenix, AZ (US)

(21) Appl. No.: 19/576,253

(22) Filed: Mar. 24, 2026

Related U.S. Application Data
(60) Provisional application No. 63/778,506, filed on Mar. 27, 2025.

(51) Int. Cl. H10P 72/30; B25J 11/00; H10P 72/76

(52) U.S. Cl. CPC H10P 72/3302; B25J 11/0095; H10P 72/7602

(57) ABSTRACT

A yoke includes a yoke body having a beam portion, a first tine portion, and a second tine portion. The yoke body defines a yoke axis. The beam portion of the yoke body is transverse to the yoke axis, the first tine portion of the yoke body extends along the yoke axis and is oblique to the beam portion of the yoke body, and the second tine portion both extends along the yoke axis and is oblique to the beam portion of the yoke body. The second tine portion of the yoke body is separated from the first tine portion of the yoke body by the yoke axis, and a lateral extent of the beam portion is greater a longitudinal extent of the first tine portion and the second portion to load and unload substrates from a dual chamber module without advancing the yoke body into process spaces.

### CROSS-REFERENCE TO RELATED APPLICATIONS

This application claims priority to U.S. Provisional Patent Application Ser. No. 63/778,506 filed Mar. 27, 2025 and titled YOKES, YOKE ASSEMBLIES AND SEMICONDUCTOR PROCESSING SYSTEMS INCLUDING YOKES, AND RELATED METHODS OF MAKING YOKES AND FORMING SEMICONDUCTOR STRUCTURES USING YOKES, the disclosure of which is hereby incorporated by reference in its entirety.

### FIELD OF INVENTION

The present disclosure generally relates to substrate handling, and more particularly to handling substrates in the semiconductor processing systems having dual chamber modules.

### BACKGROUND OF THE DISCLOSURE

End effectors are commonly employed to transfer objects, such as in industrial settings to move material between locations. Such end effectors are generally adapted to the manipulate the object being handled and may be driven by an actuator or drive operably coupled to the end effector. In some settings it may be necessary to move an object in tandem with another object, for example to limit time required to otherwise execute an intended movement and/or for accuracy, and for that reason an end effector may be paired with another end effector for tandem movement. In such applications the end effectors may be supported for independent movement relative to one another and/or be driven by separate drives, which provides flexibility to the scheduling or movement of objects in the setting. While generally satisfactory for their intended purpose, independent movement and/or independent drive of otherwise paired end effectors can add cost and/or complexity to systems employing such paired end effectors.

Such methods and systems have generally been considered suitable for their intended purpose. However, there remains a need in the art for improved yokes, yoke assemblies and semiconductor processing systems including yokes, and related methods of making yokes and forming semiconductor structures using yokes and yoke assemblies in semiconductor processing systems. The present disclosure provides a solution to this need.

### SUMMARY OF THE DISCLOSURE

A yoke is provided. The yoke includes a yoke body having a beam portion, a first tine portion, and a second tine portion. The yoke body defines a yoke axis. The beam portion of the yoke body is transverse to the yoke axis, the first tine portion of the yoke body extends along the yoke axis and is oblique to the beam portion of the yoke body, and the second tine portion both extends along the yoke axis and is oblique to the beam portion of the yoke body. The second tine portion of the yoke body is separated from the first tine portion of the yoke body by the yoke axis, and a lateral extent of the beam portion is greater than a longitudinal extent of the first tine portion and the second portion to load and unload substrates from a dual chamber module without advancing the yoke body into process spaces within the dual chamber module.

In addition to one or more of the features described above, or as an alternative, further examples of the yoke may include that the lateral extent of the beam portion is between about 1.5 times and 3 times, or is between about 1.5 times and 5 times, or between about 1.5 times and about 10 times the longitudinal extent of the first tine portion and the second tine portion of the yoke body.

In addition to one or more of the features described above, or as an alternative, further examples may include that the yoke body is formed from an aluminum-containing material.

In addition to one or more of the features described above, or as an alternative, further examples of the yoke may include that the first tine portion has a first end effector seat, and the second tine portion has a second end effector seat. A lateral separation distance between the first end effector seat and the second end effector seat may be equivalent to a rotation axis spacing defined between a first rotation axis of the first chamber and a second rotation axis of the second chamber.

In addition to one or more of the features described above, or as an alternative, further examples of the yoke may include that the beam portion of the yoke body has a rotary coupling seat. The rotary coupling seat may be laterally intermediate the first tine portion and the second tine portion of the yoke body.

An effector assembly is provided. The end effector assembly includes a yoke as described above, a first end effector, and a second end effector. The yoke body is formed from an aluminum-containing material. The first end effector is fixed to the first tine portion of the yoke body and is formed from a ceramic material. The second end effector is fixed to the second tine portion of the yoke body and is also formed from the ceramic material.

In addition to one or more of the features described above, or as an alternative, further examples of the yoke assembly may include that the first end effector has a longitudinal length that is greater than the longitudinal extent of the first tine portion of the yoke body.

In addition to one or more of the features described above, or as an alternative, further examples of the yoke assembly may include that the first end effector has a longitudinal length that is greater than the lateral extent of the beam portion of the yoke body.

In addition to one or more of the features described above, or as an alternative, further examples of the yoke assembly may include that the first end effector has a longitudinal length, wherein the longitudinal length of the first end effector is between about 1.5 times and about 5 times the longitudinal extent of the first tine portion of the yoke body, and wherein the longitudinal length of the first end effector is between about 1.5 times and about 3 times the lateral extent of the beam portion of the yoke body.

In addition to one or more of the features described above, or as an alternative, further examples of the yoke assembly may include that the first end effector has a laterally outer prong and a laterally inner prong. The laterally outer prong and the laterally inner prong may be axially separated from the first tine portion of the yoke body by a stem portion of the first end effector. The laterally inner prong of the first end effector may be parallel to the laterally outer prong of the first end effector. The laterally outer prong of the first end effector may be orthogonal relative to the beam portion of the yoke body.

In addition to one or more of the features described above, or as an alternative, further examples of the yoke assembly may include that the stem portion of the first end effector is parallel to the laterally outer prong of the first end effector. The stem portion of the first end effector may be substantially orthogonal relative to the beam portion of the yoke body.

In addition to one or more of the features described above, or as an alternative, further examples of the yoke assembly may include that the first end effector has a laterally outer prong and a laterally inner prong that are parallel to the yoke axis defined by the yoke body.

A semiconductor processing system is provided. The semiconductor processing system includes a back-end substrate transfer robot, a first chamber body, and a second chamber body. The back-end substrate transfer robot includes a yoke as described, the first tine portion of the yoke body having a first end effector seat, the second tine portion of the yoke body having a second end effector seat. The first chamber body houses a first substrate support that is supported within the first chamber body for rotation about a first rotation axis. The second chamber body houses a second substrate support that is supported within the second chamber for rotation about the second rotation axis. The first end effector seat is separated from the second end effector seat by a lateral separation distance. The lateral separation distance defined between the first end effector seat and the second end effector seat is substantially equivalent to a rotation axis spacing defined between the first rotation axis and the second rotation axis.

In addition to one or more of the features described above, or as an alternative, further examples of the semiconductor processing system may include a first injection flange and a second injection flange. The first injection flange may separate the yoke from the first chamber body and the abut the first injection flange. The second injection flange may separate the yoke from the second chamber body, the second injection flange may be laterally offset from the first injection flange, and the second chamber body may abut the second injection flange.

In addition to one or more of the features described above, or as an alternative, further examples of the semiconductor processing system may include a common process fluid source and a common exhaust source. The common process fluid source may be coupled to the first injection flange and the second injection flange. The common exhaust source may be fluidly coupled to the first injection flange by the first chamber body and the second injection flange by the second chamber body.

In addition to one or more of the features described above, or as an alternative, further examples of the semiconductor processing system may include that the common process fluid source includes a silicon-containing material layer precursor and a germanium-containing material layer precursor.

In addition to one or more of the features described above, or as an alternative, further examples of the semiconductor processing system may include a first end effector fixed to the yoke at the first end effector seat and a second end effector fixed to the yoke at the second end effector seat. The first end effector and the second end effector may be formed from quartz. The first chamber body and the second chamber body may be formed from quartz.

In addition to one or more of the features described above, or as an alternative, further examples of the semiconductor processing system may include a first link coupled to the beam portion of the yoke, a second link coupled to the first link, and a motor. The motor may be coupled to the second link and operably coupled to the first end effector and the second end effector through the yoke.

A method of making a yoke is provided. The method includes forming a yoke body defining a yoke axis by forming a beam portion transverse to the yoke axis, forming a first tine portion extending along the yoke axis and oblique relative to the beam portion of the yoke body and forming a second tine portion extending along the yoke axis and oblique relative to the beam portion of the yoke body and separated from the first tine portion by the yoke axis. The first tine portion and the second tine portion of the yoke body are formed such that a lateral extent of the beam portion of the yoke body is greater than a longitudinal extent of the first tine portion and the second tine portion to load and unload substrates from a dual chamber module without advancing the yoke body into process spaces defined within the dual chamber module.

A method of forming a semiconductor structure is provided. The method includes loading a first substrate into a first chamber using a yoke as described above and loading a second substrate into a second chamber using the yoke simultaneously with the loading of the first substrate into the first chamber using the yoke. A first material layer is deposited onto the first substrate while supported within the first chamber, a second material layer is deposited onto the second substrate simultaneously with the depositing the first material layer onto the first substrate, the first substrate with the first material layer deposited thereon is unloaded from the first chamber using the yoke, and the second substrate with the second material layer deposited thereon is unloaded from the second chamber using simultaneously with the unloading of the first substrate from the first chamber using the yoke.

This summary is provided to introduce a selection of concepts in a simplified form. These concepts are described in further detail in the detailed description of examples of the disclosure below. This summary is not intended to identify key features or essential features of the claimed subject matter, nor is it intended to be used to limit the scope of the claimed subject matter.

### BRIEF DESCRIPTION OF THE DRAWING FIGURES

The following descriptions should not be considered limiting in any way. With reference to accompanying drawings, like elements are numbered alike:

FIG. 1 is a schematic view of a semiconductor processing system including a yoke in accordance with the present disclosure, schematically showing a yoke assembly coupling two end effectors to a back-end substrate transfer robot to transfer substrates into and out of a dual chamber module (DCM) included in the semiconductor processing system;

FIG. 2 is a plan view of a portion of the semiconductor processing system of FIG. 1 according to an example of the disclosure, schematically showing simultaneous placement of substrates into a first chamber and a second chamber of the DCM using the yoke assembly;

FIG. 3 is a schematic view of a portion of the semiconductor processing system of FIG. 1 according to an example of the disclosure, showing fluid sources coupled to an exhaust source by the DCM to deposit silicon germanium and silicon layer pairs onto substrates supported within the first chamber and the second chamber;

FIG. 4 is a cross-sectional side view of the first chamber and the second chamber of the DCM included in the semiconductor processing system of FIG. 1 according to an example of the disclosure, schematically showing a crossflow architecture of the first chamber and the second chamber of the DCM included in the semiconductor processing system;

FIG. 5 is a plan view of a back-end substrate transfer robot included in the semiconductor processing system of FIG. 1 according to an example of the disclosure, showing a robot operably coupled to the yoke assembly by a first link and a second link;

FIG. 6 is a partially exploded plan view of the back-end substrate transfer robot included in the semiconductor processing system of FIG. 1 according to an example of the disclosure, showing the yoke and the end effectors exploded away from the back-end substrate transfer robot and links;

FIG. 7 is a plan view of the yoke included in the yoke assembly of FIG. 1 according to an example of the disclosure, schematically showing a beam portion of the yoke coupling a first tine portion of the yoke to a second tine portion of the yoke;

FIGS. 8 and 9 are plan and cross-sectional side views of an end effector included in the yoke assembly of FIG. 1 according to an example of the disclosure, schematically showing a stem portion of the end effector coupling a tang portion to a prong portion of the end effector, respectively;

FIGS. 10-12 are plan views of a portion of the semiconductor processing system of FIG. 1 according to an example of the disclosure, schematically showing the substrates being loaded and unloaded in the DCM using the yoke assembly without the yoke entering the chambers of the DCM included in the semiconductor processing system;

FIG. 13 is a block diagram of a method of making a yoke in accordance with the present disclosure, showing operations of the method according to an illustrative and non-limiting example of the method; and

FIG. 14 is a block diagram of a method simultaneously forming semiconductor structures on a first substrate and a second substrate, showing operations of the method according to an illustrative and non-limiting example of the disclosure.

It will be appreciated that elements in the figures are illustrated for simplicity and clarity and have not necessarily been drawn to scale. For example, the relative size of some of the elements in the figures may be exaggerated relative to other elements to help improve understanding of illustrated embodiments of the present disclosure.

### DETAILED DESCRIPTION OF EXEMPLARY EMBODIMENTS

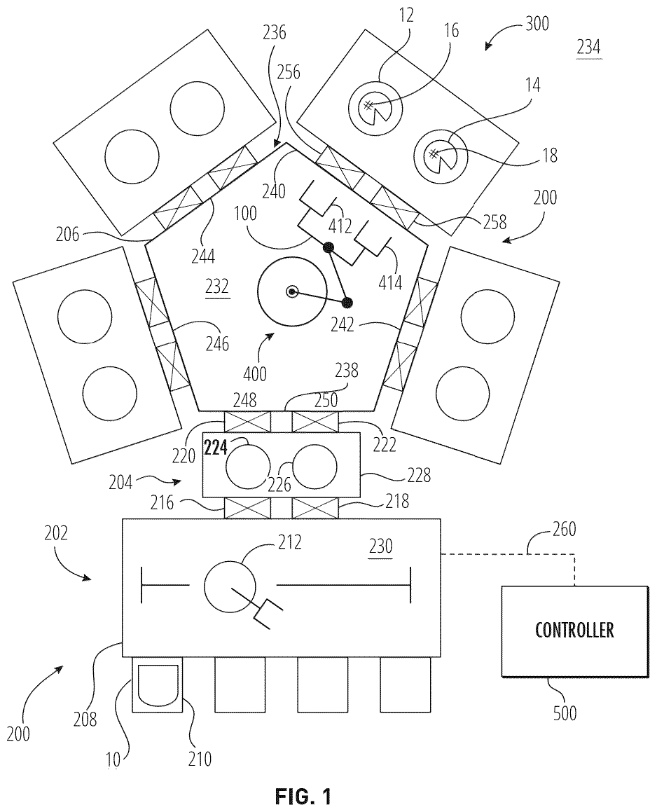

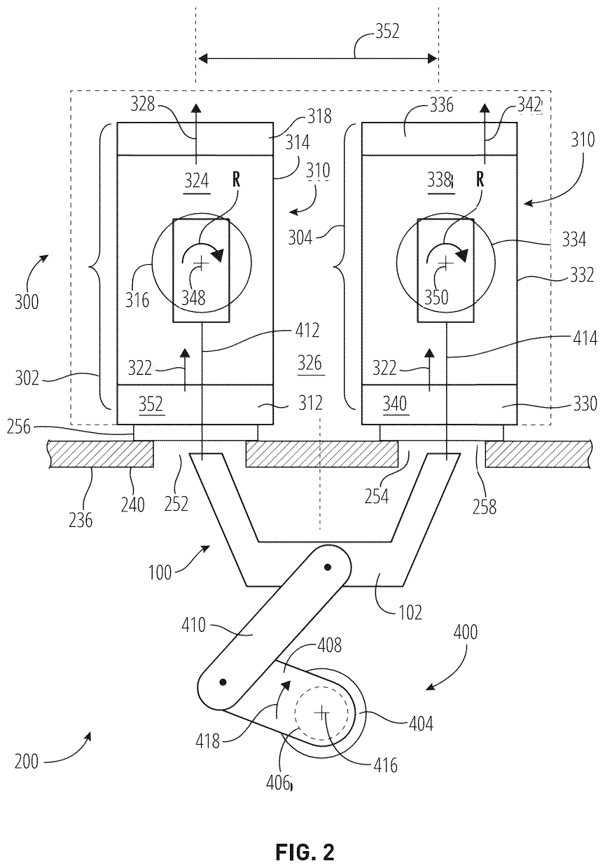

Reference will now be made to the drawings wherein like reference numerals identify similar structural features or aspects of the subject disclosure. For purposes of explanation and illustration, and not limitation, a partial view of an example of a yoke in accordance with the present disclosure is shown in FIG. 1 and is designated generally by reference character 100. Other examples of substrate transfer robots and semiconductor processing systems including yokes, and related methods of making and transferring substrates in accordance with the present disclosure, or aspects thereof, are provided in FIGS. 2-14, as will be described. The systems and methods of the present disclosure may be used to transfer substrates in semiconductor processing systems, for example in semiconductor processing systems employing dual chamber modules (DCM) including reactors having horizontal, cross-flow architectures employed to deposit semiconductor material layers using chemical vapor deposition (CVD) techniques, though the present disclosure is not limited to any particular deposition technique or reactor architecture in general.

Referring to FIG. 1, a semiconductor processing system 200 is shown according to an example of the present disclosure. In the illustrated example the semiconductor processing system 200 has a cluster-type architecture and includes an equipment front-end module (EFEM) 202, a load lock module 204, and a substrate transfer module 206 including the yoke 100. As shown and described herein the semiconductor processing system 200 also includes a process module 300, a back-end substrate transfer robot 400, and a controller 500. Although shown and described herein as including certain elements and having a cluster-type architecture it is to be understood and appreciated that the semiconductor processing system 200 may include additional elements, and/or omit elements shown and described herein, as well as having a different architecture in other examples and remain within the scope of the present disclosure.

The EFEM 202 includes an enclosure 208, a load port 210, and a front-end substrate transfer robot 212. The load port 210 is configured to seat a pod 10 containing a substrate, for example a front-opening unified pod (FOUP) housing a first substrate 12 and a second substrate 14 and abuts the enclosure 208. The enclosure 208 houses the front-end substrate transfer robot 212 and is coupled to the load lock module 204 by a first front-end gate valve 216 and a second front-end gate valve 218. The front-end substrate transfer robot 212 is supported for movement within the enclosure 208 and is configured to transfer substrates between the load port 210 and the load lock module 204 through the first front-end gate valve 216 and the second front-end gate valve 218. In the illustrated example the EFEM 202 includes four (4) load ports and two (2) front-end gate valves. As will be appreciated by those of skill in the art in view of the present disclosure, the EFEM 202 may include additional or fewer load ports and front-end gate valves and remain within the scope of the present disclosure.

As used herein the term “substrate” may refer to any underlying material or materials, including any underlying material or materials that may be modified, or upon which, a device, a circuit, or a film may be formed. A substrate may be continuous or non-continuous; rigid or flexible; solid or porous; and combinations thereof. A substrate may be in any form such as (but not limited to) a powder, a plate, or a workpiece. A substrate in the form of a plate may include a wafer in various shapes and sizes, for example, including 300-millimeter wafers. A substrate may be formed from semiconductor materials, including, for example, silicon (Si), silicon-germanium (SiGe), silicon oxide (SiO₂), gallium arsenide (GaAs), gallium nitride (GaN) and silicon carbide (SiC). A substrate may include a pattern or may be unpatterned, such as a so-called blanket-type substrate. As examples, substrates in the form of a powder may have applications for pharmaceutical manufacturing. A porous substrate may include one or more polymers. Examples of workpieces may include medical devices (for example, stents and syringes), jewelry, tooling devices, components for battery manufacturing (for example, anodes, cathodes, or separators) or components of photovoltaic cells, etc. A continuous substrate may extend beyond the bounds of a process chamber where a deposition process occurs. In some processes, a continuous substrate may move through the process chamber such that the process continues until the end of the substrate is reached. A continuous substrate may be supplied from a continuous substrate feeding system to allow for manufacture and output of the continuous substrate in any appropriate form. Non-limiting examples of continuous substrates may include sheets, non-woven films, rolls, foils, webs, flexible materials, bundles of continuous filaments or fibers (for example, ceramic fibers or polymer fibers). A continuous substrate may also comprise a carrier or sheet upon which one or more non-continuous substrate is mounted.

The load lock module 204 couples the EFEM 202 to the substrate transfer module 206 through a first intermediate gate valve 220 and a second intermediate gate valve 222. In the illustrated example the load lock module 204 includes a first transfer stage 224, a second transfer stage 226, and a load lock chamber body 228. The load lock chamber body 228 couples the first front-end gate valve 216 and the second front-end gate valve 218 to the first intermediate gate valve 220 and the second intermediate gate valve 222, houses the first transfer stage 224 and the second transfer stage 226, and is configured to separate an EFEM atmosphere 230 within the enclosure 208 from a substrate transfer module atmosphere 232 within the substrate transfer module 206 during transfer of substrates between the EFEM 202 and the substrate transfer module 206. In this respect it is contemplated that the load lock module 204 may be in selective fluid communication with an external environment 234 outside of the semiconductor processing system 200 and a purge/evacuation source, for example a vacuum pump and/or a vent fluid source, to separate the substrate transfer module atmosphere 232 from the EFEM atmosphere 230 during transfer of substrates between the EFEM 202 and the substrate transfer module 206.

In certain examples, transfer of substrates between the EFEM 202 and the substrate transfer module 206 may be accomplished by cooperation of the gate valves and the substrate transfer robots included in the semiconductor processing system 200. In this respect it is contemplated that transfer of a substrate between modules be accomplished by (a) opening a gate valve, (b) a substrate transfer robot positioning a substrate within the load lock chamber body 228, (c) the gate valve being closed, (d) the load lock chamber body 228 being evacuated or vented according to substrate destination, (e) another gate valve being opened, and (f) another substrate transfer robot removing the substrate from the load lock chamber body 228.

In the illustrated example, the semiconductor processing system 200 includes a first front-end gate valve 216 and a second front-end gate valve 218, a first transfer stage 224 and a second transfer stage 226, and a first intermediate gate valve 220 and a second intermediate gate valve 222. As will be appreciated by those of skill in the art in view of the present disclosure, the illustrated gate valve arrangement enables pairwise transfer of substrates between the EFEM 202 and the substrate transfer module 206. Advantageously, this facilitates simultaneous deposition of material layers onto substrate within multi-chamber process modules hosted by the cluster-type platform of the semiconductor processing system 200, for example the process module 300, by transferring pairs of substrates between the EFEM 202 and the process module 300 through the load lock module 204. As will be appreciated by those of skill in the art in view of the present disclosure, the load lock module 204 may include fewer or additional transfer stages as well as be coupled to either (or both) the substrate transfer module 206 and/or the EFEM 202 by fewer or additional gate valves, and remain within the scope of the present disclosure.

The substrate transfer module 206 couples the load lock module 204 to the process module 300 and in this respect includes the back-end substrate transfer robot 400 and a substrate transfer chamber body 236. The substrate transfer chamber body 236 has a plurality of facets and houses therein the back-end substrate transfer robot 400. In the illustrated example the substrate transfer chamber body 236 has a load lock facet 238, a first process module facet 240, a second process module facet 242, a third process module facet 244, and a fourth process module facet 246. The load lock facet 238 is coupled to the load lock module 204 by the first intermediate gate valve 220 and the second intermediate gate valve 222, defines a first load lock facet slit 248 and a second load lock facet slit 250 therethrough, and separates the second process module facet 242 from the fourth process module facet 246. The first process module facet 240 is adjacent to the second process module facet 242, separates the third process module facet 244 from the second process module facet 242, and is coupled to the fourth process module facet 246 by the third process module facet 244. It is contemplated that the first process module facet 240 define a first facet first transfer slit 252 and a first facet second transfer slit 254 therethrough. It is also contemplated that the first facet second transfer slit 254 be laterally adjacent to the first facet first transfer slit 252, and that the first facet first transfer slit 252 and the first facet second transfer slit 254 in turn be configured to receive therethrough a first end effector 412 carrying the first substrate 12 and a second end effector 414 carrying the second substrate 14, respectively. It is further contemplated that the first end effector 412 and the second end effector 414 in turn be operably associated with the back-end substrate transfer robot 400 by the yoke 100, the first end effector 412 fixed relative to the second end effector 414 by the yoke 100 in an end effector assembly 150.

The back-end substrate transfer robot 400 is supported within the substrate transfer chamber body 236 for movement relative to the substrate transfer chamber body 236 and is configured to transfer substrates, e.g., the first substrate 12 and the second substrate 14, pairwise between the load lock module 204 and the process module 300. In this respect it is contemplated that the back-end substrate transfer robot 400 include a motor 402 (shown in FIG. 2) having a stator 404 (shown in FIG. 2) fixed relative to the substrate transfer chamber body 236 and a rotor 406 (shown in FIG. 2) supported for rotary movement 418 relative to the stator 404, a first link 408 (shown in FIG. 2) supported for pivotable movement relative to the rotor 406 of the motor 402, a second link 410 supported for pivotable movement relative to the first link 408, and the first end effector 412 and the second end effector 414 both coupled to the second link 410 by the yoke 100. The first end effector 412 and the second end effector 414 are in turn configured to carry single substrates, for example the first substrate 12 or the second substrate 14, between the load lock module 204 and the process module 300. It is contemplated that the yoke 100 couple the first end effector 412 and the second end effector 414 to the second link 410 in fixed relation (e.g., with no degrees of freedom) to one another, and that the second link 410 in turn couple the yoke 100 to the rotor 406 of the motor 402 through the first link 408. It is also contemplated that the motor 402 in turn define rotary axis 416, the stator 404 of the motor 402 be fixed relative to the substrate transfer chamber body 236, and that the rotor 406 of the motor 402 be supported for rotary movement 418 about the rotary axis 416 of back-end substrate transfer robot 400. Although shown and described herein as having two (2) end effectors and two (2) links, it is to be understood and appreciated that the back-end substrate transfer robot 400 may include fewer or additional end effectors and/or have fewer or additional links in other examples than shown and described herein and remain within the scope of the present disclosure.

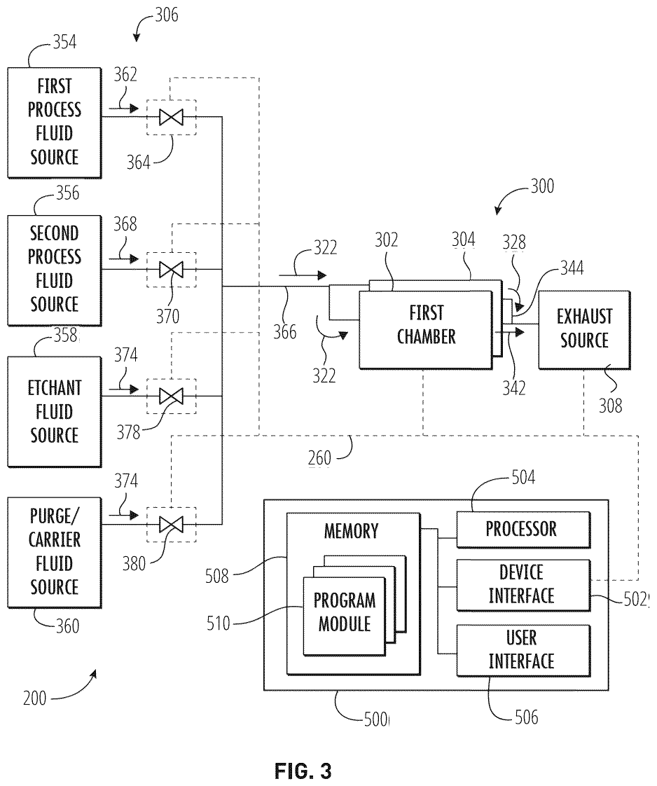

With reference to FIG. 2, a portion of the semiconductor processing system 200 including the process module 300 is shown according to an example of the disclosure. In the illustrated example to the process module 300 is a DCM and in this respect includes a first chamber 302 having a crossflow architecture 310, a second chamber 304 also having the crossflow architecture 310, a process fluid source 306 (shown in FIG. 3), and an exhaust source 308 (shown in FIG. 3). Although shown and described herein as including certain elements and having a specific architecture, it is to be understood and appreciated that the process module 300 may include additional elements and/or exclude elements shown and described herein, as well as have an architecture differing from that shown and described herein, in other examples and remain within the scope of the present disclosure.

In the illustrated example the first chamber 302 includes a first injection flange 312, a first chamber body 314, a first substrate support 316, and a first exhaust flange 318. The first injection flange 312 is positioned inboard relative to the first chamber body 314 and the first exhaust flange 318. The first injection flange 312 further abuts a first back-end gate valve 256 positioned between the first process module facet 240 of the substrate transfer chamber body 236 and the process module 300. It is contemplated that the first injection flange 312 further define a first injection flange transfer slit 320, that the first injection flange transfer slit 320 in turn be registered to the first facet first transfer slit 252 of the substrate transfer chamber body 236, and that the first facet first transfer slit 252 in turn be configured to provide communication between the first chamber 302 and the substrate transfer module 206 through the first back-end gate valve 256. It is further contemplated that the first injection flange 312 be coupled to the process fluid source 306 (shown in FIG. 3) and configured to introduce one or more process fluid 322 communicated by the process fluid source 306 into a first process space 324 within the first chamber 302.

It is contemplated that the first chamber body 314 abut the first injection flange 312, be outboard of the first injection flange 312, and bound the first process space 324. It is further contemplated that first chamber body 314 further house the first substrate support 316 within the first process space 324, that the first substrate support 316 be configured to support a substrate during deposition of a material layer onto the substrate, for example one of the first substrate 12 (shown in FIG. 1) and the second substrate 14 (shown in FIG. 1) during deposition of a first material layer 16 (shown in FIG. 1) and the second material layer 18 (shown in FIG. 1) thereon, respectively. It is contemplated that the first chamber body 314 be configured to contact the substrate with the one or more process fluid 322 introduced into the first process space 324 by the first injection flange 312 under environmental conditions selected to cause a material layer to deposit onto the substrate, for example temperature and/or pressure, and in this respect the first chamber body 314 may be a cold wall chamber body, and that the one of the first substrate 12 and the second substrate 14 may be heated using one or more external heater elements.

The first exhaust flange 318 abuts the first chamber body 314 and is separated from the first injection flange 312 by the first chamber body 314. The first exhaust flange 318 is further fluidly coupled to the first injection flange 312 by the first process space 324 defined within the first chamber 302, is coupled to the exhaust source 308 (shown in FIG. 3), and is configured to communicate a first flow of residual process fluid and/or reaction products 328 issued by the first chamber 302 to the exhaust source 308. It is contemplated that the exhaust source 308 in turn be configured to communicate the first flow of residual process fluid and/or reaction products 328 to the external environment 234 (shown in FIG. 1) outside of the semiconductor processing system 200. In this respect the exhaust source 308 may include one or more vacuum pump. In further respect, the exhaust source 308 may further include an abatement apparatus, such as a scrubber or a burn box by way of illustration and not for limitation.

The second chamber 304 is similar to the first chamber 302 and is additionally laterally offset from the first chamber 302. In this respect it is contemplated that the yoke 100 include a yoke body 102, that the yoke body 102 in turn define yoke axis 104, and that the yoke axis 104 be registered to a septum 326 by back-end substrate transfer robot 400 during simultaneous transfer of substrates between the process module 300 and the substrate transfer module 206 (shown in FIG. 1) during processing. In further respect, it is also contemplated that the second chamber 304 include a second injection flange 330, a second chamber body 332, a second substrate support 334, and a second exhaust flange 336. The second injection flange 330 is laterally offset from the first injection flange 312 and is separated from the first injection flange 312 by the septum 326. The second injection flange 330 also abuts the second back-end gate valve 258, defines therethrough a second injection flange transfer slit 340, and is registered to a second facet second transfer slit 254 such that the back-end substrate transfer robot 400 may transfer substrates between the substrate transfer module 206 and the second chamber 304 in cooperation with both the first back-end gate valve 256 and the second back-end gate valve 258. It is further contemplated that the second injection flange 330 couple the process fluid source 306 (shown in FIG. 2) to the second chamber 304 to introduce a second flow of the process fluid 322 received from the process fluid source 306 into a second process space 338 defined within the second chamber 304, the process fluid source 306 being a common or shared process fluid source 306, the second process space 338 being fluidly separated from the first process space 324.

The second chamber body 332 is additionally laterally offset from the first chamber body 314, is further separated from the first chamber body 314 by the septum 326 and is outboard of the second injection flange 330. The second chamber body 332 further abuts the second injection flange 330, bounds the second process space 338 and houses therein the second substrate support 334, and is configured to contact a substrate seated on the second substrate support 334 with the one or more process fluid 322 received from the process fluid source 306 under environmental conditions selected to cause a material layer to deposit onto the substrate, for example the second material layer 18 (shown in FIG. 1) onto the second substrate 14 (shown in FIG. 1). In this respect the second chamber 304 may be configured to maintain temperature of a substrate seated on the second substrate support 334 at a temperature substantially equivalent to temperature of a substrate seated on the first substrate support 316 within the first chamber body 314. In further respect, it is also contemplated that the second chamber 304 may be configured to maintain pressure within the second process space 338 at a pressure substantially equivalent to pressure within the first process space 324 of the first chamber 302 during deposition of a material layer onto the substrate seated on the second substrate support 334. As will be appreciated by those of skill in the art in view of the present disclosure, this allows for the simultaneous formation of material layers onto substrates seated within the first chamber 302 and the second chamber 304 of similar composition (e.g., substantially identical composition) and/or properties (e.g., substantially identical properties), enabling the semiconductor processing system 200 to have throughput greater than semiconductor processing systems having other arrangements.

The second exhaust flange 336 is laterally offset from the first exhaust flange 318, is separated from the first exhaust flange 318 by the septum 326 and abuts the second chamber body 332. The second exhaust flange 336 is further fluidly coupled to the second injection flange 330 by the second process space 338 and is in turn fluidly coupled to the exhaust source 308 (shown in FIG. 3) to communicate a flow of residual process and/or reaction products 342 issued by the second chamber 304 during deposition of the material layer onto the substrate seated on the second substrate support 334 to the external environment 234 (shown in FIG. 1) outside of the semiconductor processing system 200. In this respect it is contemplated that the exhaust source 308 may be a shared or common exhaust source 308, and that both the first chamber 302 and the second chamber 304 may be coupled to the shared or common exhaust source 308 by the first exhaust flange 318 and the second exhaust flange 336 by a shared or common exhaust manifold 344.

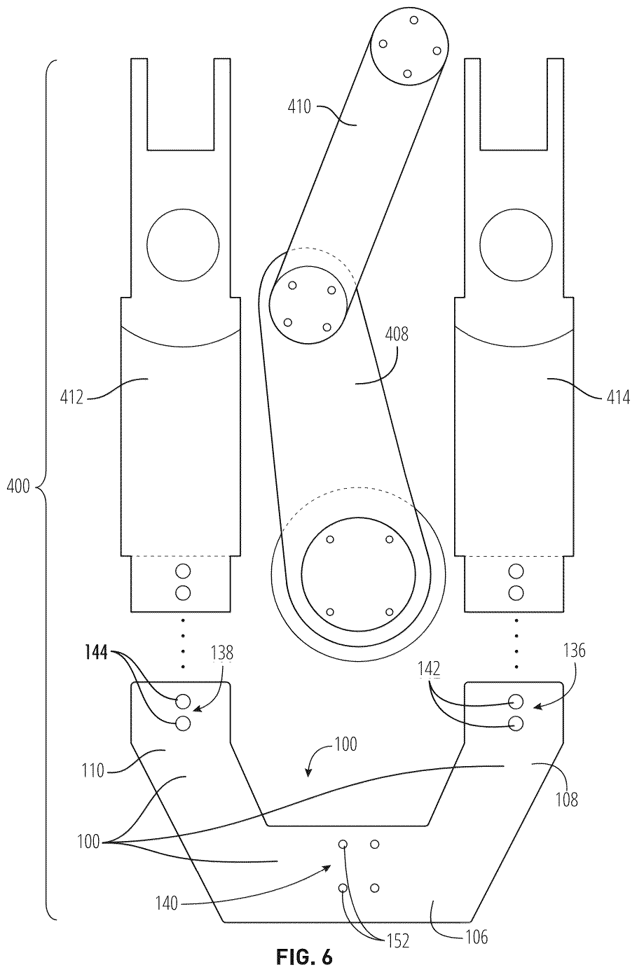

In certain examples the first substrate support 316 may be supported for rotation R about a first rotation axis 348, the second substrate support 334 may be supported for rotation R about a second rotation axis 350, and the second rotation axis 350 may be separated from the first rotation axis 348 by a rotation axis spacing 352. The rotation axis spacing 352 in such examples may be substantially equivalent to lateral separation distance 148 defined between a first end effector seat 136 (shown in FIG. 6) and a second end effector seat 138 (shown in FIG. 6) defined on the yoke body 102. As will be appreciated by those of skill in the art in view of the present disclosure, matching the rotation axis spacing 352 with the lateral separation distance 148 defined between the first end effector seat 136 and the second end effector seat 138 of the yoke body 102 may limit complexity and/or cost of the semiconductor processing system 200, for example by limiting joints and/or actuators included in the back-end substrate transfer robot 400.

In certain examples the first substrate support 316 and the second substrate support 334 may be configured to deposit a material layer only a singular substrate (i.e., one and only one) during processing. In this respect it is contemplated that the first substrate support 316 and the second substrate support 334 may be as shown and described in U.S. Pat. No. 11,959,173 to Kajbafvala et al., issued on Apr. 16, 2024, the contents of which is incorporated herein by reference in its entirety. In accordance with certain examples, the first substrate support 316 and the second substrate support 334 may be configured to each simultaneously support more than substrate during processing, the first chamber 302 and the second chamber 304 each being configured as mini-batch or batch-type reactors in such examples. In this respect the first substrate support 316 and the second substrate support 334 may be as shown and described in U.S. Patent Application Publication No. 2024/0018688 A1 to Errol et al, published on Jan. 18, 2024, the contents of which is incorporated herein by reference in its entirety. As will be appreciated by those of skill in the art in view of the present disclosure, process modules configured for deposition of material layers onto single substrates may provide between control of material layer properties, limiting variation in electrical properties of semiconductor devices formed from such material layers. As will also be appreciated by those of skill in the art in view of the present disclosure, mini-batch or batch-type reactors may provide relatively high throughput, limiting cost of ownership of semiconductor processing systems employing such reactors.

With reference to FIG. 3, a portion of the semiconductor processing system 200, including the process fluid source 306 and controller 500, are shown according to examples of the present disclosure. In the illustrated example, the process fluid source 306 incudes a first fluid source 354, a second fluid source 356, a third fluid source 358, and a fourth fluid source 360. The first fluid source 354 may include one or more silicon-containing material layer precursor 362. The first fluid source 354 may also be coupled to the process module 300 by a first fluid source mass flow controller (MFC) device 364, the first fluid source MFC device 364 in turn operably associated with the controller 500. It is contemplated that the first fluid source 354 may further be configured to communicate a flow of the silicon-containing material layer precursor 362 to both the first process space 324 (shown in FIG. 2) of the first chamber 302 and the second process space 338 (shown in FIG. 2) of the second chamber 304, for example through the first injection flange 312 (shown in FIG. 2) and the second injection flange 330 (shown in FIG. 2) coupled to the first fluid source 354 by a shared or common process fluid supply conduit 366. In this respect the first fluid source 354 may be configured to communicate the silicon-containing material layer precursor 362 as a gas, for example as a flow consisting of (or consisting essentially of) as a gas, through the shared or common process fluid supply conduit 366, the shared or common process fluid supply conduit 366 in turn coupling the process fluid source 306 to the process module 300. Examples of suitable first fluid source MFC devices include 5850 EM Series MFC devices, available from Brooks Instrument, LLC of Hatfield, Pennsylvania.

In certain examples the one or more silicon-containing material layer precursor 362 may include a chlorinated silicon-containing material layer precursor. Non-limiting examples of suitable chlorinated silicon-containing material layer precursors include dichlorosilane (SiH₂Cl₂), trichlorosilane (SiHCl₃), and silicon tetrachloride (SiCl₄). In accordance with certain examples the one or more silicon-containing material layer precursor 362 may include a non-chlorinated silicon-containing material layer precursor. Non-limiting examples of suitable non-chlorinated silicon-containing material layer precursor include silane (SiH₄), disilane (Si₂H₆), and trisilane (Si₃H₈). As will appreciated by those of skill in the art in view of the present disclosure, higher order chlorinated silicon-containing material layer precursors and/or non-chlorinated silicon-containing material layer precursors may be employed in the semiconductor processing system 200 and remain within the scope of the present disclosure.

The second fluid source 356 may be similar to the first fluid source 354 and additionally include a dopant or metal-containing material layer precursor 368. In this respect it is contemplated that the second fluid source 356 be further coupled to the first chamber 302 and the second chamber 304 by a second fluid source MFC device 370 through the first injection flange 312 (shown in FIG. 2) and the second injection flange 330 (shown in FIG. 2). It is further contemplated that the second fluid source MFC device 370 in turn be operatively associated with the controller 500, and that the second fluid source 356 be configured to communicate the dopant or metal-containing material layer precursor 368 to the process module 300 through the shared or common process fluid supply conduit 366. In certain examples the dopant or metal-containing material layer precursor 368 may include an n-type dopant like phosphorous (P) and/or arsenic (As), which may be communicated using flow(s) of arsenic (AsH₃) and/or phosphene (PH₃) by way of non-limiting example. In accordance with certain examples, the dopant or metal-containing material layer precursor 368 may include a p-type dopant, such as boron (B), which may include a dopant-containing material layer precursor like diborane (B₂H₆) by way of non-limiting example. It is also contemplated that the dopant or metal-containing material layer precursor 368 may include carbon (C) and/or or tin (Sn), which may be communicated using methylsilane (H₃SiCH₃) and/or tin tetrachloride (SnCl₄) by way of non-limiting example. It is further contemplated that the second fluid source 356 may include a metal or alloying constituent, such as germanium (Ge) as communicated using germane (GeH₄) and/or germanium tetrachloride (GeCl₄) by way of illustration and not for limitation and remain within the scope of the present disclosure.

The third fluid source 358 and the fourth fluid source 360 may also be similar to the first fluid source 354 and additionally include an etchant-containing fluid 374 (e.g., an etchant intermixed with a carrier fluid) and a carrier/purge fluid 376, respectively. In this respect the third fluid source 358 may be coupled to the process module 300 (shown in FIG. 1) by a third fluid source MFC device 378 to the first injection flange 312 (shown in FIG. 2) and the second injection flange 330 (shown in FIG. 2) of the first chamber 302 and the second chamber 304, respectively. In further respect, it is also contemplated that the third fluid source MFC device 378 may be operably associated with the controller 500, and that the third fluid source 358 configured to communicate a flow of the etchant-containing fluid 374 through the shared or common process fluid supply conduit 366 to introduce the etchant-containing fluid 374 into the first process space 324 (shown in FIG. 2) within the first chamber 302 and the second process space 338 (shown in FIG. 2) within the second chamber 304 through the first injection flange 312 and the second injection flange 330. As will be appreciated by those of skill in the art in view of the present disclosure, simultaneous communication of the etchant-containing fluid 374 to the first chamber 302 and the second chamber 304 may in turn enable simultaneous cleaning of both the first chamber 302 and the second chamber 304 of the process module 300 while limiting cost of the process module 300 in relation to process modules having separate supply conduits. In certain examples the etchant-containing fluid 374 may include a halide-containing material. Non-limiting examples of suitable halides include fluorine (F) and chlorine (Cl) containing materials such as chlorine trifluoride (ClF₃), hydrochloric (HCl) acid, and chlorine (Cl₂) gas.

It is contemplated that fourth fluid source 360 may be coupled to the process module 300 by a fourth fluid source MFC device 380 and shared or common process fluid supply conduit 366. The fourth fluid source MFC device 380 may be operably associated with the controller 500 and configured to communicate the carrier/purge fluid 376 to the first chamber 302 and the second chamber 304 through the first injection flange 312 (shown in FIG. 2) and the second injection flange 330 (shown in FIG. 2), respectively. In certain examples the fourth fluid source 360 may communicate the carrier/purge fluid 376 to the process module 300 independent of other process fluids, for example as a purge gas. In accordance with certain examples, the fourth fluid source 360 may communicate that carrier/purge fluid 376 to the process module intermixed with one or more material layer precursor, for example intermixed with the silicon-containing material layer precursor 362 and/or the dopant or metal-containing material layer precursor 368 as a carrier fluid, and/or intermixed with the etchant-containing fluid 374, such as a diluent or carrier fluid. Examples of suitable carrier/purge fluids include hydrogen (H₂) gas. Non-limiting examples of suitable carrier/purge fluids also include inert fluids such as nitrogen (N₂) gas as well as noble gases such as argon (Ar) gas, krypton (Kr) gas, and helium (He) gas.

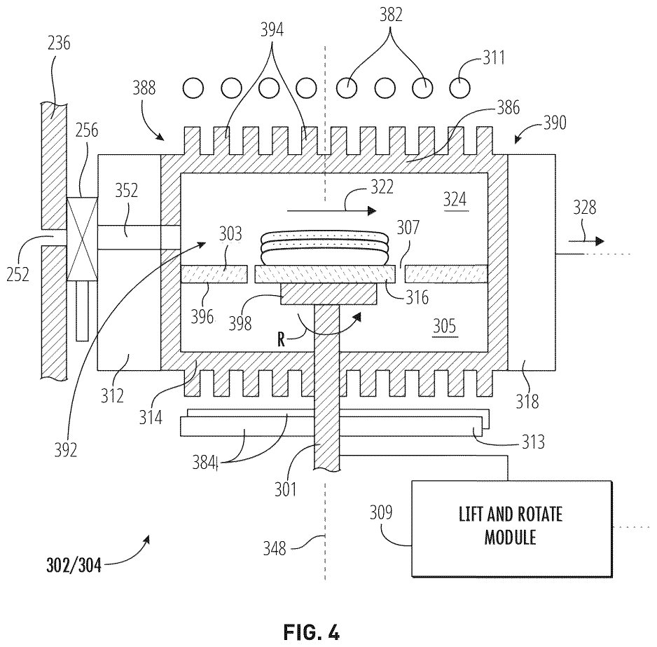

As also shown in FIG. 3 the controller 500 may include a device interface 502, a processor 504, a user interface 506, and a memory 508. The device interface 502 couples the processor 504 to a wired or wireless link 260 and therethrough to the semiconductor processing system 200, for example to the back-end substrate transfer robot 400 and the process module 300. The processor 504 is further operatively coupled to the user interface 506, for example to provide a user output and/or receive a user input therethrough and is disposed in communication with the memory 508. The memory 508 in turn includes a non-transitory machine-readable medium having a plurality of program modules 510 recorded thereon that, when read by the processor 504, cause the processor 504 to execute certain operations. Among the operations are operations of a method 700 of forming a semiconductor structure, e.g., a semiconductor structure 20 (shown in FIG. 4), as will be described. Although shown and described herein as having a specific architecture it is to be understood and appreciated that the controller 500 may have other architectures in other examples of the disclosure, such as a distributed computing architecture, and remain within the scope of the present disclosure.

With reference to FIG. 4, the first chamber 302 and the second chamber 304 of the process module 300 are shown according to an example of the disclosure. In the illustrated example the first chamber 302 has a single-substrate, horizontal, cross-flow architecture and includes the first injection flange 312, the first chamber body 314, and the first exhaust flange 318. In the illustrated example the first chamber 302 also includes a first upper heater element array 382 and a first lower heater element array 384. Although described herein in the context of the first chamber 302 it is to be understood and appreciated that the second chamber 304 may be similar (e.g., substantially identical) to the first chamber 302 in composition and arrangement.

It is contemplated that the first chamber body 314 be formed from a transparent material 386 (e.g., a ceramic material transparent to electromagnetic radiation within an infrared waveband) and has an injection end 388 and an exhaust end 390 longitudinally opposite the injection end 388. The first injection flange 312 abuts the injection end 388 of the first chamber body 314 and couples the common process fluid supply conduit 366 (shown in FIG. 3) to an interior 392 of the first chamber body 314. The first exhaust flange 318 abuts the exhaust end 390 of the first chamber body 314 and couples the first chamber body 314 to a shared or common exhaust manifold 344 (shown in FIG. 3) and therethrough to the exhaust source 308 (shown in FIG. 3). In certain examples the transparent material 386 may comprise (or consist of or consist essentially of) quartz, fused silica, and sapphire. In accordance with certain examples, the first chamber body 314 may have a plurality of external ribs 394 extending laterally about an exterior of the first chamber body 314 and longitudinally spaced apart from one another between the injection end 388 and the exhaust end 390 of the first chamber body 314. Although shown and described herein as having a plurality of external ribs and generally planar upper and lower walls, it is to be understood and appreciated that the first chamber body 314 may be unribbed, and/or have an upper wall or lower wall with an arcuate or dome-like profile, and remain within the scope of the present disclosure.

In the illustrated example the first chamber 302 also include a divider 396, the first substrate support 316 (e.g., a susceptor), a support member 398, and a shaft member 301. The divider 396 may be fixed within the interior 392 of the first chamber body 314 and formed an opaque material 303 (e.g., a material opaque to electromagnetic radiation within an infrared waveband), and further divide the interior 392 of the first chamber body 314 into the first process space 324 and a lower chamber 305. The divider 396 may further define a divider aperture 307 therethrough, the divider aperture 307 in turn coupling the first process space 324 to the lower chamber 305 within the first chamber body 314. It is contemplated that the first substrate support 316 be supported for rotation R about the first rotation axis 348 within the divider aperture 307, that the support member 398 be arranged within the lower chamber 305 and fixed in rotation relative to the first substrate support 316, and that the shaft member 301 be fixed in rotation relative to the shaft member 301 and extend through a lower wall of the first chamber body 314 and operably couple a lift and rotate module 309 to the first substrate support 316. The lift and rotate module 309 may in turn be configured to rotate the first substrate support 316 about the first rotation axis 348 and seat/unseat substrates from the first substrate support 316, for example using a lift pin actuator and lift pin arrangement. Examples of suitable lift pin actuator and lift pin arrangements include those shown and described in U.S. Patent Application Publication No. 2024/0112946 A1, filed on Sep. 27, 2023, the contents of which are incorporated herein by reference in its entirety.

In certain examples the divider 396 and/or the first substrate support 316 may be formed from a bulk carbonaceous material. Examples of suitable bulk carbonaceous materials include graphite and pyrolytic carbon. In such examples the bulk carbonaceous material may include a ceramic coating, such as a silicon carbide coating by way of non-limiting example. In accordance with certain examples, the divider 396 and/or the first substrate support 316 may be formed from a bulk ceramic material, such as silicon carbide. It is also contemplated that either (or both) the support member 398 and the shaft member 301 may be formed from the transparent material, such as that transparent material 386, and remain within the scope of the present disclosure.

The first upper heater element array 382 is supported above the first chamber body 314 and is configured to heat a substrate supported within the first chamber body 314 radiantly, for example by communicating electromagnetic radiation within an infrared waveband into the interior 392 of the first chamber body 314. In this respect it is contemplated that the first upper heater element array 382 be configured to heat a substrate supported within the first chamber body 314 to a predetermined material layer deposition temperature, for example to a predetermined material layer deposition chamber that is between about 200 degrees Celsius and about 1300 degrees Celsius, of between about 500 degrees Celsius and about 1200 degrees, or between about 500 degrees Celsius and about 750 degrees Celsius. In this respect it is contemplated that the first upper heater element array 382 may include a plurality of filament-type linear lamps 311. The plurality of filament-type linear lamps 311 may extend laterally above the first chamber body 314 and be longitudinally spaced apart from one another between the injection end 388 and the exhaust end 390 of the first chamber body 314. The plurality of filament-type linear lamps 311 may further be substantially parallel to one another.

The first lower heater element array 384 is similar to the first upper heater element array 382 and is additionally supported below the first chamber body 314. It is contemplated that the first lower heater element array 384 include a plurality of lower filament-type linear lamps 313. It is also contemplated that individual ones of the plurality of lower filament-type linear lamps 313 be laterally spaced apart from one another below the first chamber body 314, for example between laterally opposite sidewalls of the first chamber body 314, and that individual ones of the plurality of lower filament-type linear lamps 313 may be substantially parallel to one another. Although shown and described herein as both including filament-type linear lamps, it is to be understood and appreciated that either (or both) the first upper heater element array 382 and/or the first lower heater element array 384 may include bulb-type lamps, and/or other types of heater elements, and remain within the scope of the present disclosure.

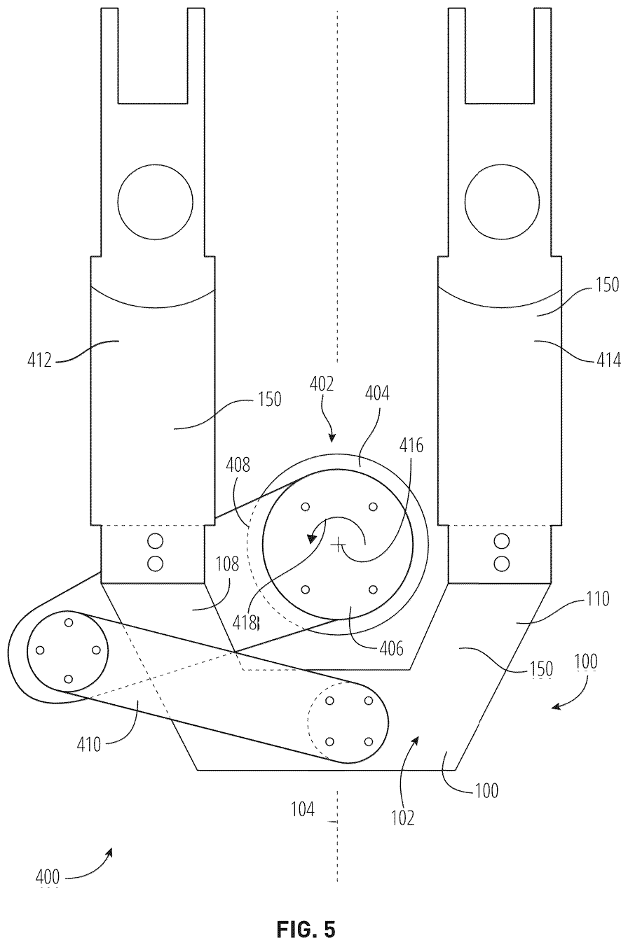

With reference to FIGS. 5-7, the yoke 100 is shown according to an example of the disclosure. As shown in FIGS. 5 and 6, the yoke 100 includes the yoke body 102. It is contemplated that the yoke body 102 define the yoke axis 104 and be configured to operably couple the first end effector 412 and the second end effector 414 to the back-end substrate transfer robot 400 (shown in FIG. 1) to simultaneously transfer substrates, e.g., the first substrate 12 (shown in FIG. 1) and the second substrate 14 (shown in FIG. 1), between the substrate transfer module 206 (shown in FIG. 1) and the process module 300 (shown in FIG. 1). In this respect it is contemplated that the yoke body 102 have a beam portion 106, a first tine portion 108, and a second tine portion 110. The beam portion 106 traverses the yoke axis 104 and may be substantially orthogonal relative to the yoke axis 104. The first tine portion 108 extends along the yoke axis 104 and may be oblique relative to the beam portion 106 of the yoke body 102. The second tine portion 110 of the yoke body 102 also extends along the yoke axis 104, may also be oblique relative to the beam portion 106 of the yoke body 102, and further be separated from the first tine portion 108 of the yoke body 102 by the yoke axis 104.

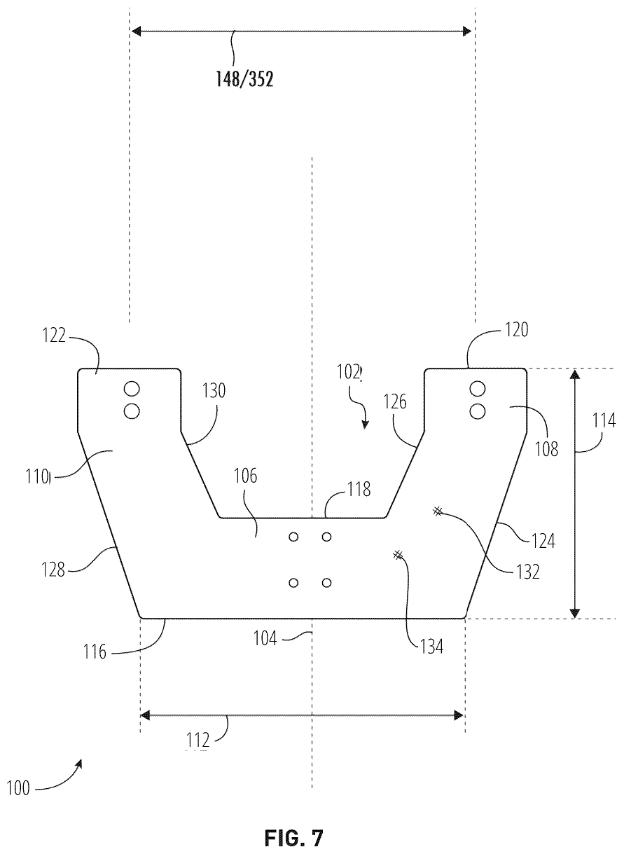

As shown in FIG. 7, the beam portion 106 of the yoke body 102 may have a lateral extent 112 substantially orthogonal relative to the yoke axis 104. The first tine portion 108 and the second tine portion 110 may both have a longitudinal extent 114 substantially parallel to the yoke axis 104. It is contemplated that the lateral extent 112 of the beam portion 106 of the yoke body 102 may be greater than the longitudinal extent 114 of the first tine portion 108 and the second tine portion 110 of the yoke body 102, for example to transfer substrates between the substrate transfer module 206 (shown in FIG. 1) and the process module 300 (shown in FIG. 1), without advancing the yoke body 102 into process spaces defined within process chambers of the process module having a crossflow architecture, for example the crossflow architecture 310 (shown in FIG. 2).

In certain examples the lateral extent 112 of the beam portion 106 of the yoke body 102 may be between about 1.5 times and about 3 times the longitudinal extent 114 of the first tine portion 108 and the second tine portion 110 of the yoke body 102. The lateral extent 112 of the beam portion 106 of the yoke body 102 may be between about 1.5 times and about 5 times the longitudinal extent 114 of the first tine portion 108 and the second tine portion 110 of the yoke body 102. The lateral extent 112 of the beam portion 106 of the yoke body 102 may be between about 1.5 times and about 10 times the longitudinal extent 114 of the first tine portion 108 and the second tine portion 110 of the yoke body 102. Advantageously, lateral extent-to-longitudinal extent ratios within these ranges enable the yoke 100 to simultaneously load and unload substrates from process chambers of a process module having a cross-flow architecture without advancing the yoke 100 into a first process space and a second process space defined with the process module, for example during loading and unloading the first substrate 12 (shown in FIG. 1) and the second substrate 14 (shown in FIG. 1) from the first process space 324 (shown in FIG. 2) within the first chamber 302 (shown in FIG. 2) and the second process space 338 (shown in FIG. 2) defined within the second chamber 304 (shown in FIG. 2) of the process module 300 (shown in FIG. 1). As will be appreciated by those of skill in the art in view of the present disclosure, ceasing advancement of the yoke 100 toward the first process space 324 and the second process space 338 prior to entering in turn enables the yoke body 102 to be formed from relatively low cost materials that could otherwise potentially introduce contamination into either (or both) the first process space 324 and the second process space 338.

As also shown in FIG. 7, the yoke body 102 may be generally plate-like or planar in contour. It is contemplated that the yoke body102 may further have an inboard edge 116, a beam portion outboard edge 118, a first tine portion outboard edge 120, and a second tine portion outboard edge 122. It is also contemplated that the yoke body 102 may further have a first tine portion outer edge 124, a first tine portion inner edge 126, a second tine portion outer edge 128, and a second tine portion inner edge 130. The inboard edge 116 and the beam portion outboard edge 118 may be axially space apart from one another and bound the beam portion 106 of the yoke body 102. The first tine portion outboard edge 120 and the second tine portion outboard edge 122 may be axially offset from the inboard edge 116 of the yoke body 102. The first tine portion outboard edge 120 and the second tine portion outboard edge 122 may further be axially separated from the inboard edge 116 by the beam portion outboard edge 118. The first tine portion outer edge 124 may couple the first tine portion outboard edge 120 to the inboard edge 116 of the yoke body 102, and the second tine portion outer edge 128 may couple the second tine portion outboard edge 122 to the inboard edge 116 of the yoke body 102.

It is contemplated that the first tine portion inner edge 126 of the yoke body 102 couple the first tine portion outboard edge 120 of the yoke body 102 to the beam portion outboard edge 118 of the yoke body 102. It is also contemplated that the second tine portion inner edge 130 of the yoke body 102 couple the second tine portion outboard edge 122 of the yoke body 102 to the beam portion outboard edge 118 of the yoke body 102. It is further contemplated that the lateral extent 112 of the beam portion 106 of the yoke body 102 may be defined along the beam portion outboard edge 118, be substantially orthogonal relative to the yoke axis 104, and terminate at the first tine portion outer edge 124 and the second tine portion outer edge 128 of the yoke body 102. In the illustrated example the longitudinal extent 114 of both the first tine portion 108 and the second tine portion 110 of the yoke body 102 extend from the beam portion outboard edge 118 to the first tine portion outboard edge 120 of the yoke body 102, are substantially parallel to the yoke axis 104, and terminate at an axial distance from the beam portion 106 of the yoke body 102 corresponding to axial position of the first tine portion outboard edge 120 and the second tine portion outboard edge 122 of the yoke body 102.

It is contemplated that the yoke body 102 may be formed from an aluminum-containing material 132. In this respect it is contemplated that the yoke body 102 may be formed from a low-copper content aluminum alloy, such as 6061 aluminum alloy by way of non-limiting examples. In further respect it is also contemplated that the aluminum-containing material 132 may have an electroless nickel coating 134 deposited onto the aluminum-containing material 132 forming the yoke body 102. In certain examples the electroless nickel coating 134 may encapsulate the yoke body 102. In accordance with certain examples, the electroless nickel coating 134 may be formed onto only a portion of the yoke body 102. As will be appreciated by those of skill in the art in view of the present disclosure, this can limit cost of the yoke 100. It is also contemplated that the yoke body 102 may be formed from a stainless-steel material or a nickel-based alloy, such as 316 stainless or Hastelloy by way of non-limiting examples and remain within the scope of the present disclosure.

With continuing reference to FIG. 6, it is contemplated that the yoke body 102 define a first end effector seat 136, a second end effector seat 138, and a rotary coupling seat 140. The first end effector seat 136 is defined on the first tine portion 108 of the yoke body 102 and is configured to fix the first end effector 412 to the yoke body 102. In this respect it is contemplated that the first end effector seat 136 may define a fastener pattern for fixation of the first end effector 412 to the first tine portion 108 of the yoke body 102. The second end effector seat 138 is similar to the first end effector seat 136, is additionally defined on the second tine portion 110 of the yoke body 102 and is configured to fix the second end effector 414 to the yoke body 102. It is contemplated that the second end effector seat 138 be laterally separated from the first end effector seat 136 by a lateral separation distance 148. In certain examples the lateral separation distance 148 may be substantially equivalent to the rotation axis spacing 352 (shown in FIG. 2) between the first rotation axis 348 (shown in FIG. 2) of the first chamber 302 (shown in FIG. 2) and the second rotation axis 350 (shown in FIG. 2) of the second chamber 304 (shown in FIG. 2). As will be appreciated by those of skill in the art in view of the present disclosure, this enables simultaneous loading and unloading of substrates into and out of the process module 300 by driving the yoke 100 axially along the yoke axis 104 using an axial stroke 460 (shown in FIG. 2), executed by back-end substrate transfer robot 400 (shown in FIG. 1), once the yoke axis 104 defined by the yoke 100 is registered to the septum 326 defined between the first chamber 302 and the second chamber 304. As will be appreciated by those of skill in the art in view of the present disclosure, the axial stroke may be executed using a singular actuator, simplifying and limiting cost of the back-end substrate transfer robot 400 (shown in FIG. 1).

The rotary coupling seat 140 may be arranged on the beam portion 106 and configured to couple the yoke 100 to the motor 402 (shown in FIG. 2), for example through the first link 408 (shown in FIG. 2) and the second link 410 (shown in FIG. 2) of the back-end substrate transfer robot 400 (shown in FIG. 1). In this respect it is contemplated that the rotary coupling seat 140 may include a fastener pattern 152, and that a rotary coupling 462 may in turn be fixed to the beam portion 106 of the yoke 100 at the fastener pattern 152 of the rotary coupling seat 140. In certain example the rotary coupling seat 140 may be laterally intermediate the first tine portion 108 and the second tine portion 110 of the yoke body 102, for example such that yoke axis intersects the rotary coupling seat 140 and/or that the rotary coupling seat 140 is evenly spaced laterally between the first tine portion 108 and the second tine portion 110 of the yoke body 102.

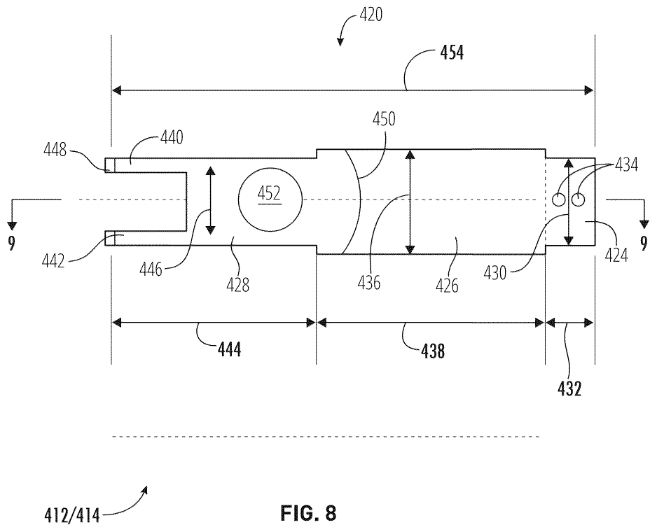

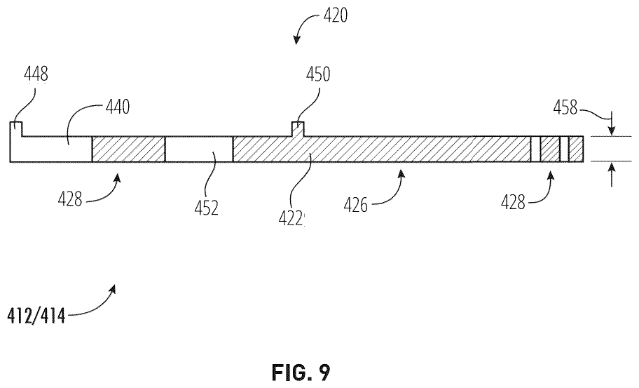

With reference to FIGS. 8 and 9, the first end effector 412 is shown according to an example of the present disclosure. A shown in FIG. 8, the first end effector 412 includes an end effector body 420. As shown in FIG. 9, it is contemplated that the end effector body 420 may be formed from an end effector material 422 (shown in FIG. 9) and be monolithic in constructure. In this respect it is contemplated that the end effector body 420 be formed by removing material from a singular workpiece using a subtractive manufacturing technique, the end effector body 420 having a singular one-piece construction with no welds or joints. As will be appreciated by those of skill in the art, forming the end effector body 420 as monolithic one-piece body may limit the thickness 458 of the end effector body 420, limiting height of the first injection flange transfer slit 320 (shown in FIG. 2) defined within the first injection flange 312 (shown in FIG. 2) of the first chamber 302 (shown in FIG. 1), simplifying arrangement of the first chamber 302. In certain examples the end effector material 422 may comprise (or consist of or consist essentially of) a ceramic material. In this respect it is contemplated that the first end effector 412 may be formed from a ceramic material such as quartz, fused silica, and/or sapphire. Although the first end effector 412 is described herein, it is to be understood and appreciated that the second end effector 414 may be substantially identical to the first end effector 412 in certain examples of the disclosure.

With continuing reference to FIG. 8, the end effector body 420 has a tang portion 424, a stem portion 426, and a prong portion 428. The tang portion 424 has a tang portion lateral width 430 and a tang portion longitudinal length 432 and defines a fastener pattern 434 corresponding to a fastener pattern 142 of the first end effector seat 136 (shown in FIG. 6). The stem portion 426 extends longitudinally from the tang portion 424, has a stem portion lateral width 436 and a stem portion longitudinal length 438, and may be demarcated from the tang portion 424 by lateral step in width of the end effector body 420. The prong portion 428 of the end effector body 420 in turn extends longitudinally from the stem portion 426 and may also be demarcated from the stem portion 426 by a lateral step in width. The prong portion 428 may further terminate at a laterally outer prong 440 and a laterally inner prong 442 and have a prong portion longitudinal length 444 and a prong portion lateral width 446.

In certain examples outboard tips 448 of the laterally outer prong 440 and the laterally inner prong 442 may protrude from the end effector body 420. The laterally outer prong 440 and the laterally inner prong 442 may protrude from a generally planar surface of the end effector body 420 and may be separated from the first tine portion 108 of the yoke body 102 by the stem portion 426 of the end effector body 420. The laterally inner prong 442 of the end effector body 420 may be substantially parallel to the laterally outer prong 440 of the end effector body 420, and the laterally outer prong 440 of the end effector body 420 may be substantially orthogonal relative to the beam portion 106 of the yoke body 102 included in the yoke 100. The laterally outer prong 440 and the laterally inner prong 442 of the end effector body 420 may both be parallel to the yoke axis 104. In accordance with certain examples, the stem portion 426 of the end effector body 420 may both be parallel to the laterally outer prong 440 of the end effector body 420 and substantially orthogonal relative to the beam portion of the yoke body 102. It is contemplated that, in accordance with certain examples of the disclosure, the outboard tips 448 of the laterally outer prong 440 and the laterally inner prong 442 may further cooperate with a rim 450 also protruding from the generally planar surface of the end effector body 420, the rim 450 in turn laterally spanning the stem portion 426 of the end effector body 420 to render a substrate carried by the first end effector 412 captive.

In certain examples the outboard tips 448 and the rim 450 may be generally arcuate in lateral trace and in this respect may in circumference and diametric separation to render a 300-millimeter wafer captive therebetween while carried by the end effector body 420. In accordance with certain examples, the prong portion 428 of the end effector body 420 may define therethrough a frequency tuning aperture 452. In such examples the frequency tuning aperture 452 may cooperate with geometry of the end effector body 420 and a predetermined substrate transfer acceleration/deceleration value employed during loading and unloading of substrates from the process module 300 (shown in FIG. 1) to shift a natural frequency of the end effector body 420 away from impulses associated with loading and unloading of substrates from the process module 300. As will be appreciated by those of skill in the art in view of the present disclosure, this may ensure centering of substrates on substrate supports arranged within process chambers of the process module 300, limiting variation in material layers deposited onto the substrates.

In certain examples the stem portion lateral width 436 may be greater than the tang portion lateral width 430. In accordance with certain examples, the stem portion lateral width 436 may be greater than the prong portion lateral width 446. It is also contemplated that the stem portion lateral width 436 may be greater than both the prong portion lateral width 446 and the tang portion lateral width 430. Advantageously, examples of the first end effector 412 having a stem portion lateral width that greater than both the tang portion lateral width and the stem portion lateral width enable to frequency tuning aperture 452 to be sized to shift natural frequency of the end effector body 420 away from excitation frequencies associated with load and unload speeds associated with the first chamber 302 (shown in FIG. 2) and the second chamber 304 (shown in FIG. 2) while maintaining stiffness sufficient to limit sag of the end effector body 420 due to heating, enabling the end effector body 420 to a longitudinal length 454 sufficient to load and unload substrates from a deposition module having the crossflow architecture 310 (shown in FIG. 2). In this respect it is contemplated that the longitudinal length 454 of the end effector body 420 may be between about 300 millimeters and about 600 millimeters, or between about 400 millimeters and about 600 millimeters, or even between about 500 millimeters and about 600 millimeters, enabling employment of the first end effector 412 in a chamber module having the crossflow architecture 310 (shown in FIG. 2).

In certain examples the stem portion longitudinal length 438 may be greater than the tang portion longitudinal length 432. In accordance with certain examples, the stem portion longitudinal length 438 may be greater than the prong portion longitudinal length 444. It is also contemplated that the stem portion longitudinal length 438 may be greater than both the tang portion longitudinal length 432 and the prong portion longitudinal length 444. In this respect it is contemplated that stem portion longitudinal length 438 may be greater than a substrate pocket width 456 defined between the outboard tips 448 of the prong portion 428 and the rim 450 spanning the stem portion 426 of the end effector body 420. For example, the stem portion longitudinal length 438 may be between about 300 millimeters and about 400 millimeters, or between about 300 millimeters and about 500 millimeters, or even between about 300 millimeters and about 600 millimeters. Advantageously, this enables the end effector body 420 to have a thickness 458 sufficient for passage through a lateral slit of an injection flange of chamber module having the crossflow architecture 310 (shown in FIG. 2), for example the lateral widths of both the first facet first transfer slit 252 (shown in FIG. 2) of the first injection flange 312 (shown in FIG. 2), transfer chamber lateral slit while limiting (or preventing) sag of the end effector body 420 when carrying a substrate at relatively high load and/or unload temperatures, for example at load and/or unload temperatures that are between about 300 degrees Celsius and about 500 degrees Celsius).

In certain examples the longitudinal length 454 of the end effector body 420 may be greater than the longitudinal extent 114 of the first tine portion 108 and the second tine portion 110 of the yoke body 102. In accordance with certain examples, the stem portion longitudinal length 438 may be greater than the longitudinal extent 114 of the first tine portion 108 and the second tine portion 110 of the yoke body 102. It is also contemplated that the substrate pocket width 456 of the end effector body 420 may be greater than the longitudinal extent of the first tine portion 108 and the second tine portion 110 of the end effector body 420. Advantageously, this enables loading and unloading substrates from process modules having the crossflow architecture 310 (shown in FIG. 2) without advancing the yoke 100 into the process space defined with the process modules, enabling fabrication of the yoke 100 from a relatively inexpensive and easily machined material that is incompatible with the process space defined within the process module, limiting cost of the semiconductor processing system employing the yoke 100.

In certain examples the yoke body 102 may be formed from an aluminum-containing material, such as 6061 aluminum alloy. The first end effector 412 may fixed to the first tine portion 108 of the yoke body 102, the second end effector 414 may be fixed to the second tine portion 110 of the yoke body 102, for example at the first end effector seat 136 and the second end effector seat 146 of the yoke body 102, respectively. In such examples the first end effector 412 and the second end effector 414 may be formed from a ceramic material, such as quartz by way of non-limiting example. Advantageously, forming the yoke body 102 from an aluminum-containing material like 6061, and the first end effector 412 and the second end effector 414 from a ceramic material like quartz, enables an end effector assembly including these elements to be employed in a dual chamber arrangement employing a first chamber and a second chamber having a cross-flow architecture while limiting complexity and cost of the back-end substrate transfer robot employed to load and unload substrates from the first chamber and the second chamber, such as in the process module 300 (shown in FIG. 1). In such examples either (or both) the first end effector 412 and the second end effector 414 may have a longitudinal length, e.g., the longitudinal length 454 (shown in FIG. 8), that is greater than the longitudinal extent 114 of the first tine portion 108 and/or the second tine portion 110 of the yoke body 102 included in the yoke 100.

In certain examples the first end effector 412 and/or the second end effector 414 may have a longitudinal length, e.g., the longitudinal length 454, that is greater than the lateral extent 112 of the beam portion 106 of the yoke body 102 included in the yoke 100. For example the longitudinal length 454 of either (or both) the first end effector 412 and the second end effector 414 may be between about 1.5 times and about 5 times the longitudinal extent of either (or both) the first tine portion 108 and the second tine portion 110 of the yoke body 102 included in the yoke 100, or between about 1.5 times and about 4 times the longitudinal extent of either (or both) the first tine portion 108 and the second tine portion 110 of the yoke body 102 included in the yoke 100, or even between about 1.5 times and about 3 times the longitudinal extent of either (or both) the first tine portion 108 and the second tine portion 110 of the yoke body 102 included in the yoke 100. Advantageously, end effector assemblies having end effector longitudinal lengths-to-longitudinal extent of the tine portions of the yoke operably coupled to the end effector load and unload substrates from chambers employed in a DCM with limited (or substantially none) risk of introducing metallic contamination into chamber bodies having crossflow architectures.

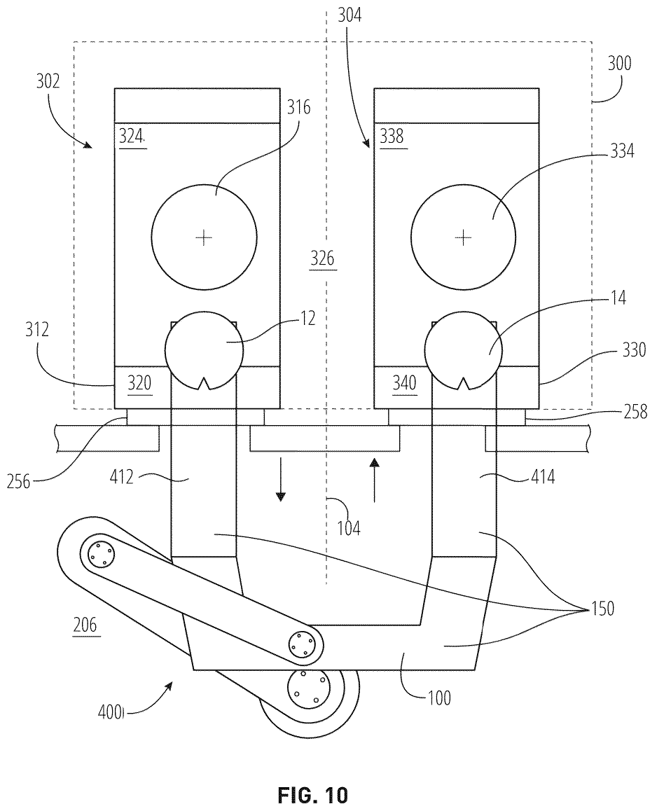

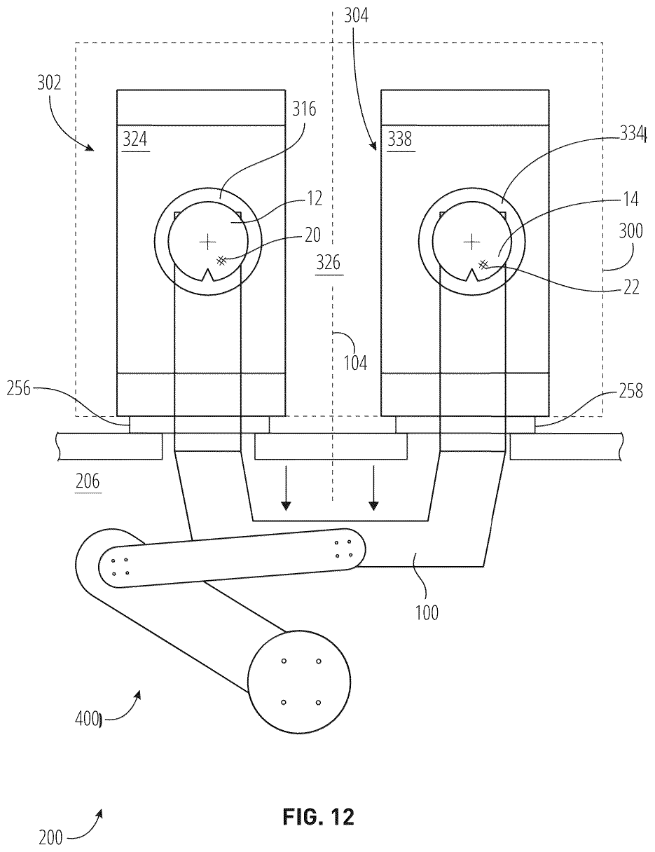

With reference to FIGS. 10-12, loading and unloading of the first substrate 12 and the second substrate 14 into the first chamber 302 and the second chamber 304 of the process module 300 using the yoke 100 are shown to form a first semiconductor structure 20 (shown in FIG. 12) and a second semiconductor structure 22 (shown in FIG. 12) on the first substrate 12 and the second substrate 14, respectively, are shown according to an example of the present disclosure. As shown in FIG. 10, it is contemplated that the first substrate 12 and the second substrate 14 be transferred onto the first end effector 412 and the second end effector 414 of the end effector assembly 150 within the substrate transfer module 206 of the semiconductor processing system 200, for example from the EFEM 202 (shown in FIG. 1) and through the load lock module 204 (shown in FIG. 1). Once the first substrate 12 and the second substrate 14 are transferred to the first end effector 412 and the second end effector 414, respectively, it is contemplated that back-end substrate transfer robot 400 register the yoke 100 to the process module 300, for example such that the yoke axis 104 defined by the yoke body 102 extends through the septum 326 defined between the first chamber 302 and the second chamber 304. Advantageously, registration of the yoke 100 to the process module 300 may be accomplished using a singular rotary movement 418 (shown in FIG. 5) of the back-end substrate transfer robot 400 to simultaneously register the first end effector 412 to the first injection flange transfer slit 320 defined within the first injection flange 312 of the first chamber 302 and the second injection flange transfer slit 340 defined in the second injection flange 330 of the second chamber 304 due to fixation of the second end effector 414 relative to the first end effector 412 by the yoke 100.

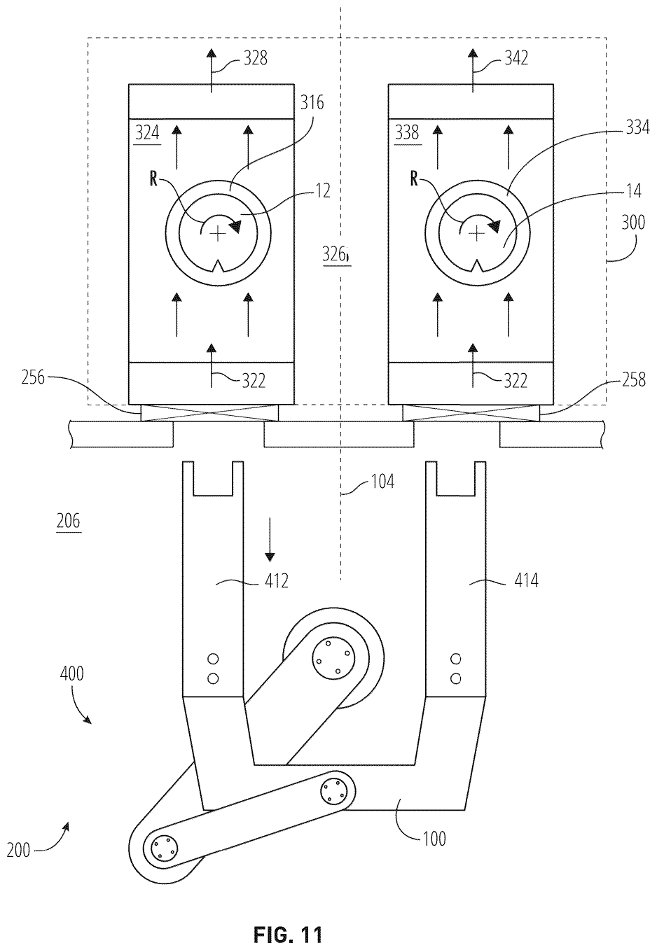

As shown in FIG. 11, it is contemplated that the first back-end gate valve 256 and second back-end gate valve 258 be opened, and that the yoke 100 advanced toward the first process module facet 240 of the substrate transfer chamber body 236 by the back-end substrate transfer robot 400. It is further contemplated that advancement of the yoke 100 simultaneously drive the first end effector 412 and the second end effector 414 axially along the yoke axis 104 into the first chamber 302 and the second chamber 304 carrying the first substrate 12 and the second substrate 14 such that, at a conclusion of a transfer stroke, the first end effector 412 supports the first substrate 12 within the first process space 324 at a location above the first substrate support 316 and the second end effector 414 supports the second substrate 14 within the second process space 338 at a location above the second substrate support 334. The first substrate 12 and the second substrate 14 may thereafter be transferred to the first substrate support 316 and the second substrate support 334, respectively, the first end effector 412 and the second end effector 414 simultaneously withdrawn from the first chamber 302 and the second chamber 304 by the back-end substrate transfer robot 400 using the yoke 100, and the first back-end gate valve 256 and the second back-end gate valve 258 closed to fluidly separate the first process space 324 and the second process space 338 from one another and the substrate transfer module atmosphere 232 (shown in FIG. 1). Once the second process space 338 is fluidly separated from the first process space 324, the process fluid 322 may be provided to both the first process space 324 and the second process space 338 and the first material layer 16 and the second material layer 18 simultaneously deposited onto the first substrate 12 and the second substrate 14, respectively.

In certain examples the first material layer 16 and the second material layer 18 may be individual layers of layer pairs forming a first semiconductor structure 20 and a second semiconductor structure 22 (shown in FIG. 12) overlaying the first substrate 12 (shown in FIG. 12) and the second substrate 14, respectively. In this respect the first material layer 16 may be a silicon germanium material layer 16A and a silicon material layer 16B may be deposited onto the silicon germanium material layer 16A to deposit one of a plurality of first layer pairs 16C forming the first semiconductor structure 20 (shown in FIG. 4), and the second material layer 18 may be a second silicon germanium material layer 18A and a silicon material layer 18B may be deposited onto the second silicon germanium material layer 18A to deposit one of a plurality of second layer pairs 18C forming a second semiconductor structure 22. Forming of the first semiconductor structure 20 and the second semiconductor structure 22 may be accomplished, for example by cyclically and simultaneously flowing the dopant or metal-containing material layer precursor 368 with the silicon-containing material layer precursor 362 and thereafter flowing the silicon-containing material layer precursor 362 without the dopant or metal-containing material layer precursor 368 to the first chamber 302 and the second chamber 304, respectively. As will be appreciated by those of skill in the art in view of the present disclosure, simultaneously forming the first semiconductor structure 20 and the second semiconductor structure 22 may limit the number of process fluid conduits required to communicate material layer precursors to the first chamber 302 and the second chamber 304, simplifying the arrangement of the semiconductor processing system 200 and/or limiting cost of the semiconductor processing system 200.

As shown in FIG. 12, once the first material layer 16 and the second material layer 18 are deposited flow of the process fluid 322 (shown in FIG. 11) to the first process space 324 and the second process space 338 may cease. Once flow of the process fluid 322 to the first process space 324 and the second process space 338 ceases, the first back-end gate valve 256 and the second back-end gate valve 258 may be opened and the first end effector 412 and the second end effector 414 advanced toward the first chamber 302 and the second chamber 304 by the back-end substrate transfer robot 400 using the yoke 100 to position the first end effector 412 and the second end effector 414 above the first substrate support 316 and the second substrate support 334, respectively. Once positioned above the first substrate support 316 and the second substrate support 334, the first substrate 12 and the second substrate 14 may be transferred to the first end effector 412 and the second end effector 414, respectively, and the first substrate 12 and the second substrate 14 thereafter simultaneously carried out of the first chamber 302 and the second chamber 304 by the first end effector 412 and the second end effector 414 by the back-end substrate transfer robot 400 using the yoke 100. Advantageously, unloading of the first substrate 12 and the second substrate 14 from the first chamber 302 and the second chamber 304 may be accomplished without independent movement of either of the first end effector 412 and the second end effector 414 relative to the other of the first end effector 412 and the second end effector 414, simplifying the arrangement and/or limiting cost of the semiconductor processing system 200 by limiting the need for joints and actuators for such independent movement.

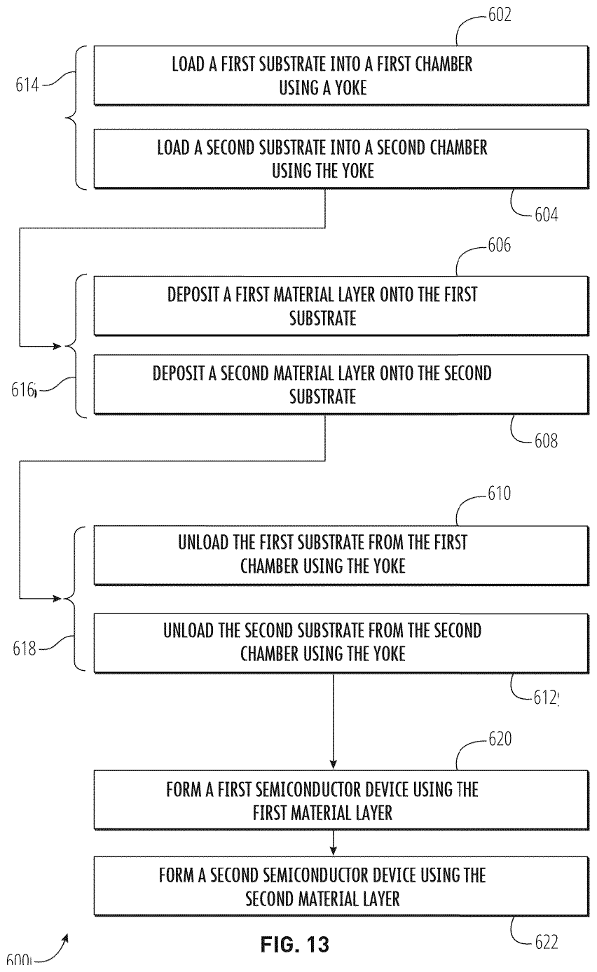

With reference to FIG. 13, a method 600 of forming semiconductor structures, e.g., the first semiconductor structure 20 (shown in FIG. 4) and the second semiconductor structure 22 (shown in FIG. 12), is shown. Forming 600 the semiconductor structures includes loading a first substrate into a first chamber, e.g., the first substrate 12 (shown in FIG. 1) into the first chamber 302 (shown in FIG. 2), and loading a second substrate into a second chamber, e.g., the second substrate 14 (shown in FIG. 1) into the second chamber 304 (shown in FIG. 2), using a first end effector fixed relative to a second end effector by a yoke, e.g., the first end effector 412 (shown in FIG. 1) and the second end effector 414 (shown in FIG. 1) fixed to one another by the yoke 100 (shown in FIG. 1), as shown with box 602 and box 604. Forming 600 the semiconductor structures also includes depositing a first material layer on the first substrate while supported within a first process space defined in the first chamber, e.g., the first material layer 16 (shown in FIG. 1) on the first substrate while the first substrate is supported within the first process space 324 (shown in FIG. 2) of the first chamber, and depositing a second material layer on the second substrate while supported within a second process space defined in the second chamber, e.g., the second material layer 18 (shown in FIG. 1) on the second substrate while the second substrate is supported within the second process space 338 (shown in FIG. 2) of the second chamber, as shown with box 606 and box 608. Forming 600 the semiconductor structures further includes removing the first substrate from the first chamber and the second substrate from the second chamber subsequent to deposition of the first material layer onto the first substrate and the second material layer onto the second substrate using the yoke, as shown with box 610 and box 612. As shown with bracket 614, the first substrate and the second substrate may be simultaneously loaded into the first chamber and the second chamber using the yoke. As shown with bracket 616, the first material layer and the second material layer may be simultaneously deposited on the first substrate and the second substrate, respectively. As shown with bracket 618, the first substrate and the second substrate may be simultaneously removed from the first chamber and the second chamber using the yoke. It is contemplated that a first semiconductor device and a second semiconductor device, such logic or memory devices having three-dimensional architectures, may be formed using the first material layer deposited onto the first substrate and the second material layer deposited onto the second substrate, as shown with box 620 and box 622.

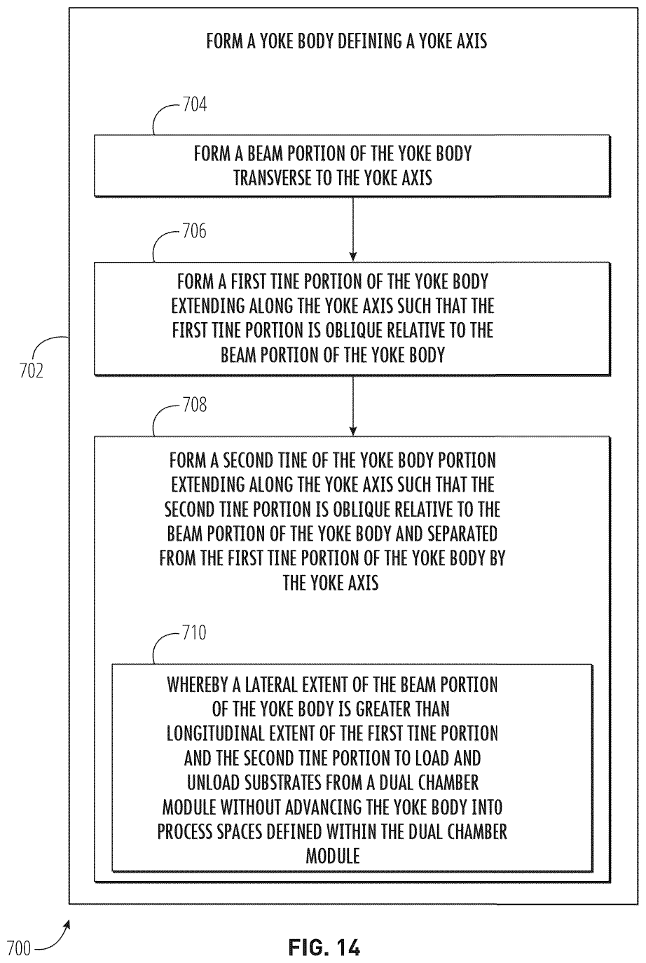

With reference to FIG. 14, a method 700 of making a yoke, e.g., the yoke 100 (shown in FIG. 1), is provided. The method 700 includes forming a yoke body such that the yoke body defines a yoke axis, e.g., the yoke body 102 (shown in FIG. 2) defining the yoke axis 104 (shown in FIG. 2), as shown with box 702. Forming 702 the yoke body includes forming a beam portion of the yoke body transverse to the yoke axis and having a lateral extent, e.g., the beam portion 106 (shown in FIG. 5) of the yoke body lateral to the yoke axis and having the lateral extent 112 (shown in FIG. 7), as shown with box 704. Forming 702 the yoke body also includes forming a first tine portion and a second tine portion of the yoke body both extending along the yoke axis, e.g., the first tine portion 108 (shown in FIG. 7) and the second tine portion 110 (shown in FIG. 7), as shown with box 706 and box 708. It is contemplated that the first tine portion and the second tine portion be formed such that the first tine portion and the second tine portion are oblique relative to the yoke axis, as also shown with box 706 and box 708, and that the first tine portion and the second tine portion be formed such that longitudinal (e.g., axial) extents of both the first tine portion and the second tine portion be less than the lateral extent of the beam portion of the yoke body, as shown with box 710.

Although this disclosure has been provided in the context of certain embodiments and examples, it will be understood by those skilled in the art that the disclosure extends beyond the specifically described embodiments to other alternative embodiments and/or uses of the embodiments and obvious modifications and equivalents thereof. In addition, while several variations of the embodiments of the disclosure have been shown and described in detail, other modifications, which are within the scope of this disclosure, will be readily apparent to those of skill in the art based upon this disclosure. It is also contemplated that various combinations or sub-combinations of the specific features and aspects of the embodiments may be made and still fall within the scope of the disclosure. It should be understood that various features and aspects of the disclosed embodiments can be combined with, or substituted for, one another in order to form varying modes of the embodiments of the disclosure. Thus, it is intended that the scope of the disclosure should not be limited by the particular embodiments described above.

The headings provided herein, if any, are for convenience only and do not necessarily affect the scope or meaning of the devices and methods disclosed herein.

1. A yoke, comprising:
a yoke body defining a yoke axis, the yoke body having:
a beam portion transverse to the yoke axis;
a first tine portion extending along the yoke axis and oblique relative to the beam portion of the yoke body;
a second tine portion extending along the yoke axis, oblique relative to the beam portion of the yoke body, and separated from the first tine portion by the yoke axis,
wherein a lateral extent of the beam portion of the yoke body is greater than a longitudinal extent of the first tine portion and the second tine portion to load and unload substrates from a dual chamber module without advancing the yoke body into process spaces defined within a first chamber and a second chamber.

2. The yoke of claim 1, wherein the lateral extent of the beam portion is between about 1.5 times and about 10 times the longitudinal extent of the first tine portion and the second tine portion of the yoke body.

3. The yoke of claim 1, wherein the yoke body is formed from an aluminum-containing material.

4. The yoke of claim 1, wherein the first tine portion has a first end effector seat, wherein the second tine portion has a second end effector seat, and wherein a lateral separation distance between the first end effector seat and the second end effector seat is substantially equivalent to a rotation axis spacing defined between a first rotation axis of the first chamber and a second rotation axis of the second chamber.

5. The yoke of claim 1, wherein the beam portion has a rotary coupling seat that is laterally intermediate the first tine portion and the second tine portion of the yoke body.

6. An end effector assembly, comprising:
a yoke body defining a yoke axis, the yoke body having:
a beam portion transverse to the yoke axis;
a first tine portion extending along the yoke axis and oblique relative to the beam portion of the yoke body;
a second tine portion extending along the yoke axis, oblique relative to the beam portion of the yoke body, and separated from the first tine portion by the yoke axis,
wherein a lateral extent of the beam portion of the yoke body is greater than a longitudinal extent of the first tine portion and the second tine portion to load and unload substrates from a dual chamber module without advancing the yoke body into process spaces defined within a first chamber and a second chamber, wherein the yoke body is formed from an aluminum-containing material;
a first end effector fixed to the first tine portion of the yoke body and formed from a ceramic material; and
a second end effector fixed to the second tine portion of the yoke body and formed from the ceramic material.

7. The end effector assembly of claim 6, wherein the first end effector has a longitudinal length that is greater than the longitudinal extent of the first tine portion of the yoke body.

8. The end effector assembly of claim 6, wherein the first end effector has a longitudinal length that is greater than the lateral extent of the beam portion of the yoke body.

9. The end effector assembly of claim 6, wherein the first end effector has a longitudinal length that is between about 1.5 times and about 5 times the longitudinal extent of the first tine portion of the yoke body, and wherein the longitudinal length of the first end effector is between about 1.5 times and about 3 times the lateral extent of the beam portion of the yoke body.

10. The end effector assembly of claim 6, wherein the first end effector has a laterally outer prong and a laterally inner prong, the laterally outer prong and the laterally inner prong axially separated from the first tine portion of the yoke body by a stem portion of the first end effector, the laterally inner prong parallel to the laterally outer prong of the first end effector, the laterally outer prong orthogonal to the beam portion of the yoke body.

11. The end effector assembly of claim 10, wherein the stem portion of the first end effector is parallel to the laterally outer prong of the first end effector, and wherein the stem portion of the first end effector is substantially orthogonal relative to the beam portion of the yoke body.

12. The end effector assembly of claim 10, wherein the first end effector has a laterally outer prong and a laterally inner prong, and wherein the laterally outer prong and the laterally inner prong are both parallel to the yoke axis defined by the yoke body.

13. A semiconductor processing system, comprising:
a back-end substrate transfer robot including a yoke, the yoke comprising:
a yoke body defining a yoke axis, the yoke body having:
a beam portion transverse to the yoke axis;
a first tine portion extending along the yoke axis and oblique relative to the beam portion of the yoke body;
a second tine portion extending along the yoke axis, oblique relative to the beam portion of the yoke body, and separated from the first tine portion by the yoke axis,
wherein a lateral extent of the beam portion of the yoke body is greater than a longitudinal extent of the first tine portion and the second tine portion to load and unload substrates from a dual chamber module without advancing the yoke body into process spaces defined within a first chamber and a second chamber, wherein the first tine portion of the yoke body has a first end effector seat, wherein the second tine portion of the yoke body has a second end effector seat;
a first chamber body housing a first substrate support, the first substrate support supported within the first chamber body for rotation about a first rotation axis;
a second chamber body housing a second substrate support, the second substrate support within the second chamber for rotation about second rotation axis;
wherein the first end effector seat is separated from the second end effector seat by a lateral separation distance; and
wherein the lateral separation distance is substantially equivalent to a rotation axis spacing defined between the first rotation axis and the second rotation axis.

14. The semiconductor processing system of claim 13, further comprising:
a first injection flange separating the yoke from the first chamber body, wherein the first chamber body abuts the first injection flange; and
a second injection flange separating the yoke from the second chamber body, the second injection flange laterally offset from the first injection flange, wherein the second chamber body abuts the second injection flange.

15. The semiconductor processing system of claim 14, further comprising:
a common process fluid source coupled to the first injection flange and the second injection flange; and
a common exhaust source fluidly coupled to the first injection flange by the first chamber body and the second injection flange by the second chamber body.

16. The semiconductor processing system of claim 15, wherein the common process fluid source includes a silicon-containing material layer precursor and a germanium-containing material layer precursor.

17. The semiconductor processing system of claim 13, further comprising:
a first end effector fixed to the yoke at the first end effector seat;
a second end effector fixed to the yoke at the second end effector seat;
wherein the first end effector and the second end effector are formed from quartz; and
wherein the first chamber body and the second chamber body are formed from quartz.

18. The semiconductor processing system of claim 17, further comprising:
a first link coupled to the beam portion of the yoke;
a second link coupled to the first link; and
a motor coupled to the second link and operably coupled to the first end effector and the second end effector through the yoke.

19. A method of making a yoke, comprising:
forming a yoke body defining a yoke axis by:
forming a beam portion transverse to the yoke axis;
forming a first tine portion extending along the yoke axis such that the first tine portion is oblique relative to the beam portion of the yoke body; and
forming a second tine portion extending along the yoke axis such that the second tine portion is oblique relative to the beam portion of the yoke body and separated from the first tine portion of the yoke body by the yoke axis,
wherein a lateral extent of the beam portion of the yoke body is greater than a longitudinal extent of the first tine portion and the second tine portion to load and unload substrates from a dual chamber module without advancing the yoke body into process spaces defined within the dual chamber module.

20. A method of forming a semiconductor structure, comprising:
at a yoke including a yoke body defining a yoke axis and having a beam portion transverse to the yoke axis; a first tine portion extending along the yoke axis and oblique relative to the beam portion of the yoke body; a second tine portion extending along the yoke axis, the second tine portion oblique relative to the beam portion of the yoke body and separated from the first tine portion by the yoke axis, a lateral extent of the beam portion of the yoke body greater than a longitudinal extent of the first tine portion and the second tine portion,
loading a first substrate into a first chamber using the yoke;
loading a second substrate into a second chamber using the yoke simultaneously with the loading of the first substrate into the first chamber;
depositing a first material layer onto the first substrate;
depositing a second material layer onto the second substrate simultaneously with the depositing the first material layer onto the first substrate;
unloading the first substrate from the first chamber using the yoke; and
unloading the second substrate from the second chamber simultaneously with the unloading of the first substrate from the first chamber using the yoke.
